(19) United States
(12) Patent Application Publication
(10) Pub. No.: US 2026/0304843 A1
(43) Pub. Date: Oct. 1, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Ming-Yen CHUANG, Hsinchu (TW); Katherine H. CHIANG, Hsinchu (TW)

(73) Assignee: Taiwan Semiconductor Manufacturing Company, Ltd., Hsinchu (TW)

(21) Appl. No.: 19/095,827

(22) Filed: Mar. 31, 2025

(51) Int. Cl. H10D 30/67; H10D 30/01; H10D 62/80; H10D 62/86

(52) U.S. Cl. CPC H10D 30/6738; H10D 30/0316; H10D 30/6732; H10D 30/6739; H10D 30/6755; H10D 62/86; H10D 62/875

(57) ABSTRACT

A semiconductor device includes a bottom gate electrode, a gate insulating layer, an active layer, a dielectric layer, two interfacial layers and two source/drain electrodes. The gate insulating layer is disposed between the bottom gate electrode and the active layer. The dielectric layer is disposed on the active layer and the two interfacial layers are formed in first and second portions (i.e., contact areas) of the active layer and between the two source/drain electrodes and the active layer. The source/drain electrodes are electrically connected to the active layer through the interfacial layers and a channel region is form between the two source/drain electrodes.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit in accordance with some embodiments of the disclosure.

FIG. 2 is a schematic diagram of a semiconductor device according to an embodiment of the present disclosure.

FIGS. 3 to 7 are schematic diagrams illustrating a method for manufacturing the semiconductor device of FIG. 2 according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

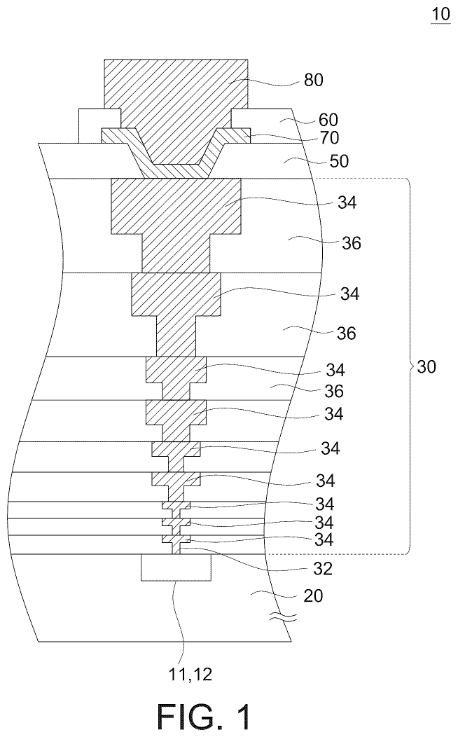

FIG. 1 is a schematic cross-sectional view of an integrated circuit 10 in accordance with some embodiments of the disclosure. In some embodiments, the integrated circuit 10 includes a substrate 20, an interconnection structure 30, a passivation layer 50, a post-passivation layer 60, a conductive pad 70, and a conductive terminal 80. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions may be doped with p-type or n-type dopants. For example, the doped regions may be doped with p-type dopants, such as boron or BF₂; n-type dopants, such as phosphorus or arsenic; and/or combinations thereof. In some embodiments, these doped region may serve as source/drain regions of a semiconductor device 12 (e.g., transistor 11) embedded in the substrate 20. Depending on the types of the dopants in the doped regions, the transistor 11 may be referred to as n-type transistor or p-type transistor. In some embodiments, the transistor 11 may further includes a metal gate and a channel under the metal gate. The channel is located between the source region and the drain region to serve as a path for electron to travel when the transistor 11 is turned on. In some embodiments, the transistor 11 may be formed using suitable Front-end-of-line (FEOL) process. Depending on the circuit requirement, the transistor 11 may be completely embedded in the substrate 20 or partially embedded in the substrate 20. For simplicity, one transistor 11 is shown in FIG. 1. However, it should be understood that more than one transistors 11 may be embedded in the substrate 20 depending on the application of the integrated circuit 10. When multiple transistors 11 are present, these transistors 11 may be separated by shallow trench isolation (STI; not shown) located between two adjacent transistors 11. That is, in some embodiments, the STI are also embedded in the substrate 20.

As illustrated in FIG. 1, the interconnection structure 30 is disposed on the substrate 20. In some embodiments, the interconnection structure 30 includes a plurality of conductive vias 32, a plurality of conductive patterns 34, and a plurality of dielectric layers 36. As illustrated in FIG. 1, the conductive patterns 34 are embedded in the dielectric layers 36. On the other hand, the conductive vias 32 penetrate through the dielectric layers 36. In some embodiments, the conductive patterns 34 located at different level heights are connected to one another through the conductive vias 32. In other words, the conductive patterns 34 are electrically connected to one another through the conductive vias 32. In some embodiments, the bottommost conductive vias 32 are connected to the transistor 11 embedded in the substrate 20. In other words, the bottommost conductive vias 32 establish electrical connection between the transistor 11 and the conductive patterns 34 of the interconnection structure 30. As illustrated in FIG. 1, the bottommost conductive via 32 is connected to the metal gate of the transistor 11 or the semiconductor device 12. It should be noted that in some alternative cross-sectional views, the bottommost conductive vias 32 are also connected to source/drain regions of the transistor 11 or the semiconductor device 12. That is, in some embodiments, the bottommost conductive vias 32 may be referred to as “contact structures” of the transistor 11 or the semiconductor device 12.

In some embodiments, a material of the dielectric layers 36 includes polyimide, epoxy resin, acrylic resin, phenol resin, benzocyclobutene (BCB), polybenzooxazole (PBO), or any other suitable polymer-based dielectric material. Alternatively, the dielectric layers 36 may be formed of oxides or nitrides, such as silicon oxide, silicon nitride, or the like. The dielectric layers 36 may be formed by suitable fabrication techniques such as spin-on coating, chemical vapor deposition (CVD), plasma-enhanced chemical vapor deposition (PECVD), or the like.

In some embodiments, a material of the conductive patterns 34 and the conductive vias 32 includes aluminum, titanium, copper, nickel, tungsten, or alloys thereof. The conductive patterns 34 and the conductive vias 32 may be formed by electroplating, deposition, and/or photolithography and etching. In some embodiments, the conductive patterns 34 and the underlying conductive vias 32 are formed simultaneously. It should be noted that the number of the dielectric layers 36, the number of the conductive patterns 34, and the number of the conductive vias 32 illustrated in FIG. 1 are merely for illustrative purposes, and the disclosure is not limited thereto. In some alternative embodiments, fewer or more layers of the dielectric layers 36, the conductive patterns 34, and/or the conductive vias 32 may be formed depending on the circuit design. The passivation layer 50, the conductive pad 70, the post-passivation layer 60, and the conductive terminals 80 will be illustrated in detail later.

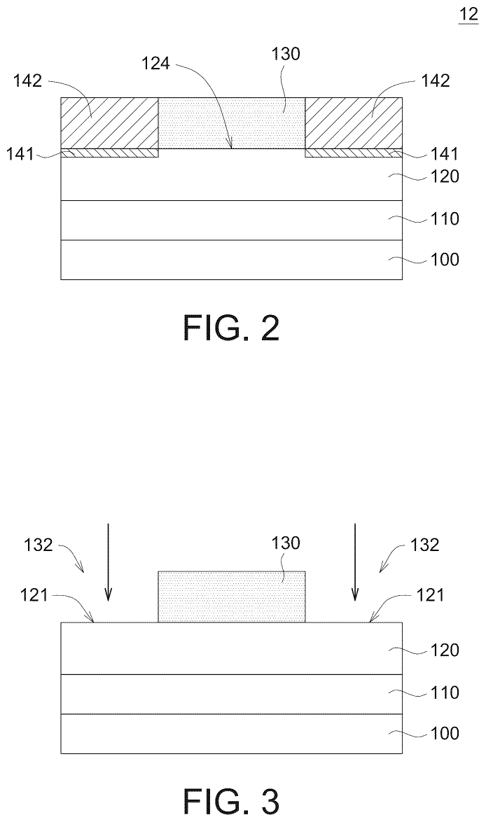

Referring to FIG. 2, FIG. 2 is a schematic diagram of a semiconductor device 12 according to an embodiment of the present disclosure. The semiconductor device 12 may be the transistor 11 in or above the substrate 20, as shown in FIG. 1. Although the following embodiments take the thin film transistor having the bottom gate electrode 100 as an example, the present disclosure is not limited thereto, and the semiconductor device 12 can also be implemented by other embodiments. The semiconductor device 12 of FIG. 2 can be formed by the manufacturing method shown in FIGS. 3 to 7.

The semiconductor device 12 includes a bottom gate electrode 100, a gate insulating layer 110, an active layer 120, a dielectric layer 130, two interfacial layers 141 and two source/drain electrodes 142. The gate insulating layer 110 is disposed between the bottom gate electrode 100 and the active layer 120. The dielectric layer 130 is disposed on a first portion of the active layer 120 and the two interfacial layers 141 are formed in second portions (i.e., contact areas) of the active layer 120 and between the two source/drain electrodes 142 and the active layer 120. The source/drain electrodes 142 are electrically connected to the active layer 120 through the interfacial layers 141 and a channel region 124 is form between the two source/drain electrodes 142. The source/drain electrodes 142 may be used as source/drain regions of the transistor 11 for connecting to the bottommost conductive vias 32 in FIG. 1.

In FIG. 2, each of the interfacial layers 141 is located between one of the source/drain electrodes 142 and the active layer 120. The interfacial layer 141 is self-mixed in the contact areas of the active layer 120 for work function matching between each of the two source/drain electrodes 142 and the active layer 120.

The material of the bottom gate electrode 100 may include silver (Ag), aluminum (Al), copper (Cu), tungsten (W), nickel (Ni), titanium (Ti), niobium (Nb), molybdenum (Mo), vanadium (V), cobalt (Co), chromium (Cr) or a combination thereof. In some embodiments, the material of the bottom gate electrode 100 may include metal nitride, such as titanium nitride (TiN), tantalum nitride (TaN), tungsten nitride (WN), niobium nitride (NbN), molybdenum nitride (MoN), vanadium nitride (VN), cobalt nitride (CoN), chromium nitride (CrN), nickel nitride (Ni₃N) and the like, but the disclosure is not limited thereto. In some embodiments, the material of the bottom gate electrode 100 may include polysilicon or doped silicon.

In FIG. 2, the gate insulating layer 110 is formed on the top of the bottom gate electrode 100. The gate insulating layer 110 may be a dielectric material including silicon oxide (SiOx), silicon nitride, silicon oxynitride, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate, zirconium aluminate, zirconium oxide, titanium oxide, aluminum oxide (Al₂O₃), a hafnium dioxide-alumina (HfO₂—Al₂O₃) alloy, hafnium oxide: oxide Lanthanum (HfOx:LaOx), hafnium oxide: strontium oxide (HfOx:SrO), hafnium zirconium oxide (HZO) doped with cerium oxide (CeOx) or a combination thereof.

One common gate insulating layer 110 is silicon oxide. While a thinner silicon oxide gate dielectric is also more susceptible to tunneling and has a greater gate leakage. In addition, high-k dielectric materials used as the gate insulating layer 110 have been introduced into field effect transistors (FETs) for better transistor performance and the demand of low operation voltage. The high-k dielectric materials may be hafnium oxide (HfOx), hafnium zirconium oxide (HZO) or other dielectrics with a dielectric constant more than 6. While any suitable gate dielectric material may be used, some examples of the present disclosure use a high-k dielectric material as the gate insulating layer 110 to reduce leakage current, reduce threshold voltage, and/or optimize the operation of the transistor. In FIG. 2, although the gate insulating layer 110 is shown as a single layer, the gate insulating layer 110 may include multiple insulating layers, and each insulating layer may include a different dielectric material.

In FIG. 2, the active layer 120 is formed on the top of the gate insulating layer 110, and the material of the active layer 120 includes metal oxide semiconductors. In some embodiments, the metal oxide semiconductor comprises at least one of In, Ga, and Zn. Other elements among Ti, Al, W, Ce, Sn, Zr, Nd, Sm and Lu can be selected for addition formation element of metal oxide semiconductor. The material of the active layer 120 may include indium gallium zinc oxide (InGaZnO, IGZO), tungsten-doped indium oxide (InWO), indium zinc oxide (InZnO), indium tin oxide (InSnO), Zinc oxide(ZnO), gallium oxide (GaOx), indium oxide (InOx), aluminum zinc oxide (AZO), or a combination thereof.

FIGS. 3 to 7 are schematic diagrams illustrating a method for manufacturing the semiconductor device 12 of FIG. 2 according to an embodiment of the present disclosure. The method for manufacturing the semiconductor device 12 includes the following steps. Referring to FIG. 3, a bottom gate electrode 100, a gate insulating layer 110 and an active layer 120 are formed in order. The bottom gate electrode 100 may be a laminated gate electrode including multiple layers, and the thickness of the bottom gate electrode 100 may be about 20 nm to 50 nm. For example, the bottom gate electrode 100, the gate insulating layer 110 and the active layer 120 are formed by chemical vapor deposition (CVD), physical vapor deposition (PVD) or atomic layer deposition (ALD).

The active layer 120 is, for example, a metal oxide semiconductor, which can be formed by, for example, direct current (DC) sputtering or radio frequency (RF) sputtering. In the DC sputtering or RF sputtering, a sputtering target having the same composition as the metal oxide semiconductor of the active layer 120. In FIG. 3, a dielectric layer 130 is formed on the active layer 120. Some portion of the dielectric layer 130 is etched to form at least one opening 132 (or via hole). The openings 132 defines the positions of the source/drain electrode material to be filled. The top surfaces 121 of the active layer 120 exposed from the openings 132 of the dielectric layer 130 are used as second portions (i.e., contact areas) for the subsequent formed source/drain electrodes 142.

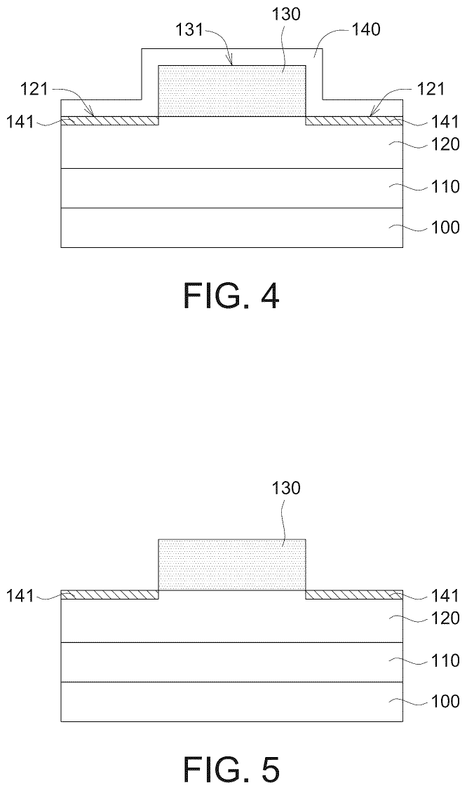

Referring to FIG. 4, a metal oxide layer 140 is formed. For example, aluminum oxide (AlOx) is formed on the top portion 131 and sidewall portions of the dielectric layer 130 and the contact surfaces of the active layer 120 at the top surface 121. The metal oxide layer 140 is formed by CVD, PVD or ALD. In one embodiment, the thin film transistor (TFT) with IGZO active layer and AlOx layer deposited on the contact areas of the active layer improves the field effect mobility in the interfacial region between the IGZO active layer and the AlOx layer. The ion bombardment during the AlOx deposition process breaks the In-O bond in IGZO active layer and produces oxygen ions (O₂⁻). The sputtered amorphous AlOx promotes the segregation of O₂⁻. An In-rich oxide (InO) layer with a high oxygen vacancy concentration is formed at the interfacial region, resulting in an increase in the carrier concentration in the interfacial layer 141. The InO layer (i.e., the interfacial layer 141) is also a suitable interfacial layer for work function matching. The “work function” matching between the source/drain electrodes 142 and the active layer 120 is the key for creating a low contact resistance. By applying AlOx induced self-intermix methods in the present disclosure, an interfacial layer 141 is self-formed to bridge the work function gap between a metal oxide semiconductor (i.e., the active layer 120) and a metal electrode (i.e., the source/drain electrodes 142). In addition to the electrical performance, reliability tests including long-term exposure in ambient environment also show improved results with the InO interfacial layer.

Referring to FIG. 5, the metal oxide layer 140 is removed by etching process, while the interfacial layer 141 remains un-etching due to selective etching. In some embodiments, the indium concentration of the interfacial layer 141 is higher than that of the active layer 120. For example, the indium concentration of the interfacial layer 141 is in a range between about 10¹⁷ and about 10¹⁹ atoms/cm³, and the indium concentration of the IGZO active layer 120 is in a range between about 10¹⁵ and about 10¹⁷ atoms/cm³. That is, more indium atoms inside the IGZO active layer 120 segregate at the interfacial region to form indium-rich oxide (InO) as the interfacial layer 141.

In some embodiments, other oxides, for example, zinc oxide (ZnO), gallium oxide (GaO), and nickel oxide (NiO) can also be selectively used as the interfacial layer 141 by self-intermix methods. The present disclosure is not limited thereto.

In some embodiments, the thickness of the interfacial layer 141 is lower than that of the active layer 120. For example, the thickness of the interfacial layer 141 is in a range between about 0.1 nm and about 5 nm, and the thickness of the active layer 120 is in a range between about 1 nm and about 100 nm.

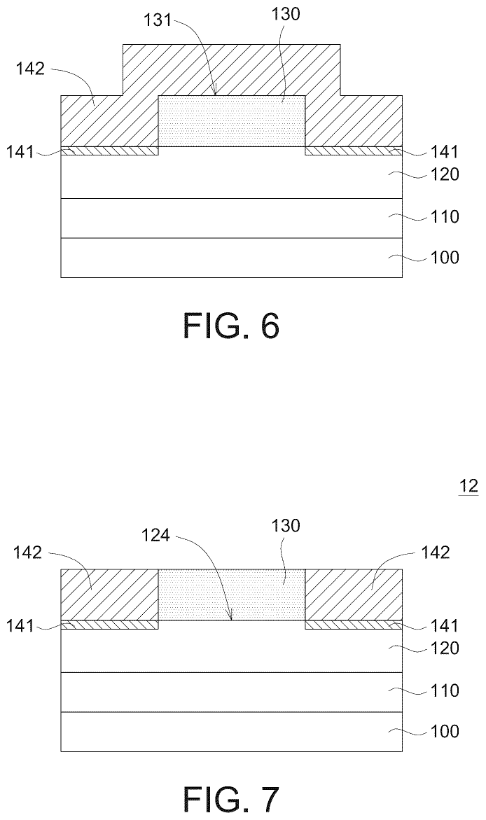

Referring to FIG. 6, a source/drain electrode material (that is, 142) is form by CVD, PVD or ALD. For example, the source/drain electrode material is formed on the top surface 131 and side surfaces of the dielectric layer 130 and filled into the openings 132 to cover the interfacial layers 141, and excess portions of the source/drain electrode material above the dielectric layer 130 is removed by chemical-mechanical polishing (CMP) in FIG. 7 to make the top surface of the dielectric layer 130 and the top surface of the source/drain electrodes 142 coplanar.

The formation method of the source/drain electrodes 142 is not limited in the present disclosure, for example, a metal film is formed by a magnetron sputtering method or a radio frequency (RF) sputtering method, and then a wet etching is performed with an etchant of hydrogen peroxide, phosphoric acid, nitric acid or acetic acid to remove excess portion of the metal film above the dielectric layer 130, thereby forming the source/drain electrodes 142.

Referring to FIG. 7, the semiconductor device 12 may be the transistor 11 provided in a front-end-of-line (FEOL) of semiconductor manufacturing process, where various components in a substrate are connected with the interconnection structure 30 and conductive vias in corresponding dielectric layers 36 as shown in FIG. 1.

The material of the source/drain electrodes 142 may include silver (Ag), aluminum (Al), copper (Cu), tungsten (W), nickel (Ni), titanium (Ti), niobium (Nb), molybdenum (Mo), vanadium (V), cobalt (Co), chromium (Cr) or a combination thereof. In some embodiments, the material of the source/drain electrodes 142 may include metal nitride, such as titanium nitride (TiN), tantalum nitride (TaN), tungsten nitride (WN), niobium nitride (NbN), molybdenum nitride (MoN), vanadium nitride (VN), cobalt nitride (CoN), chromium nitride (CrN), nickel nitride (Ni₃N) and the like, but the disclosure is not limited thereto. In some embodiments, the material of the source/drain electrodes 142 may include polysilicon or doped silicon.

For example, when titanium nitride (TiN) or tungsten nitride (WN) is selected as the source/drain electrodes 142, the indium oxide (InO) layer can be used as the interfacial layer 141 to reduce contact resistance between the source/drain electrodes 142 and the active layer 120.

As illustrated in FIG. 1, the passivation layer 50, the conductive pads 70, the post-passivation layer 60, and the conductive terminals 80 are sequentially formed on the interconnection structure 30. In some embodiments, the passivation layer 50 is disposed on the topmost dielectric layer 36 and the topmost conductive patterns 34. In some embodiments, the passivation layer 50 has a plurality of openings partially exposing each topmost conductive pattern 34. In some embodiments, the passivation layer 50 may be a silicon oxide layer, a silicon nitride layer, a silicon oxy-nitride layer, or a dielectric layer formed by other suitable dielectric materials. The passivation layer 50 may be formed by suitable fabrication techniques such as HDP-CVD, PECVD, or the like.

In some embodiments, one of the conductive pads 70 is formed over the passivation layer 50. In some embodiments, the conductive pad 70 extends into the openings of the passivation layer 50 to be in direct contact with the topmost conductive patterns 34. That is, the conductive pad 70 is electrically connected to the interconnection structure 30. In some embodiments, the conductive pad 70 includes aluminum pads, copper pads, titanium pads, nickel pads, tungsten pads, or other suitable metal pads. The conductive pads 70 may be formed by, for example, electroplating, deposition, and/or photolithography and etching. It should be noted that the number and the shape of the conductive pads 70 illustrated in FIG. 1 are merely for illustrative purposes, and the disclosure is not limited thereto. In some alternative embodiments, the number and the shape of the conductive pads 70 may be adjusted based on demand.

In some embodiments, the post-passivation layer 60 is formed over the passivation layer 50 and the conductive pad 70. In some embodiments, the post-passivation layer 60 is formed on the conductive pad 70 to protect the conductive pad 70. In some embodiments, the post-passivation layer 60 has a plurality of contact openings partially exposing each conductive pad 70. The post-passivation layer 60 may be a polyimide layer, a PBO layer, or a dielectric layer formed by other suitable polymers. In some embodiments, the post-passivation layer 60 is formed by suitable fabrication techniques such as HDP-CVD, PECVD, or the like.

As illustrated in FIG. 1, one of the conductive terminals 80 is formed over the post-passivation layer 60 and the conductive pad 70. In some embodiments, the conductive terminal 80 extends into the contact openings of the post-passivation layer 60 to be in direct contact with the corresponding conductive pad 70. That is, the conductive terminal 80 is electrically connected to the interconnection structure 30 through the conductive pad 70. In some embodiments, the conductive terminal 80 is a conductive pillar, a conductive post, a conductive ball, a conductive bump, or the like. In some embodiments, a material of the conductive terminal 80 includes a variety of metals, metal alloys, or metals and mixture of other materials. For example, the conductive terminal 80 may be made of aluminum, titanium, copper, nickel, tungsten, tin, and/or alloys thereof. The conductive terminal 80 is formed by, for example, deposition, electroplating, screen printing, or other suitable methods. In some embodiments, the conductive terminal 80 is used to establish electrical connection with other components (not shown) subsequently formed or provided.

The present disclosure relates to a semiconductor device and a manufacturing method thereof, in which AlOx induced self-intermix methods are applied so that an interfacial layer is formed to bridge the work function gap between a metal oxide semiconductor (i.e., the active layer) and a metal electrode (i.e., the source/drain electrodes). For example, the thin film transistor (TFT) with IGZO active layer and AlOx layer deposited on the contact areas of the active layer improves the field effect mobility in the interfacial region between the IGZO active layer and the AlOx layer. The ion bombardment during the AlOx deposition process breaks the In—O bond in IGZO active layer and produces oxygen ions (O₂⁻). The sputtered amorphous AlOx promotes the segregation of O₂⁻. An In-rich oxide (InO) layer with a high oxygen vacancy concentration is formed at the interfacial region, resulting in an increase in the carrier concentration in the interfacial layer.

According to some embodiments of the present disclosure, a semiconductor device is provided. The semiconductor device includes a bottom gate electrode 100, a gate insulating layer 110, an active layer 120, a dielectric layer 130, two interfacial layers 141 and two source/drain electrodes 142. The gate insulating layer 110 is disposed between the bottom gate electrode 100 and the active layer 120. The dielectric layer 130 is disposed on the active layer 120 and the two interfacial layers 141 are formed in first and second portions (i.e., contact areas) of the active layer 120 and between the two source/drain electrodes 142 and the active layer 120. The source/drain electrodes 142 are electrically connected to the active layer 120 through the interfacial layers 141 and a channel region 124 is form between the two source/drain electrodes 142.

According to some embodiments of the present disclosure, a method for manufacturing a semiconductor device is provided as follows. A bottom gate electrode 100, a gate insulating layer 110 and an active layer 120 are formed in order from bottom to top. A dielectric layer 130 is formed on the active layer 120. The dielectric layer 130 is etched to form at least one opening 132 to expose a portion of the active layer 120. A metal oxide layer 140 is formed on the exposed portion, and an interfacial layer 141 between the active layer and the metal oxide layer 140 is self-formed in the exposed portion. The metal oxide layer 140 is removed to expose the interfacial layer 141. A source/drain electrode 142 is formed on the interfacial layer 141 and electrically connected to the active layer 120 through the interfacial layer 141.

According to some embodiments of the present disclosure, a transistor is provided. The transistor includes a bottom gate electrode, a gate insulating layer, an indium gallium zinc oxide (IGZO) layer, a first indium oxide layer and a first source/drain electrode. The gate insulating layer is disposed on the bottom gate electrode. The IGZO layer is disposed on the gate insulating layer, wherein the gate insulating layer is disposed between the bottom gate electrode and the IGZO layer. The first indium oxide layer is formed in a first portion of the IGZO layer. The first source/drain electrode is formed on the first indium oxide layer, wherein the first source/drain electrode is electrically connected to the IGZO layer through the first indium oxide layer, and indium concentration of the first indium oxide layer is higher than indium concentration of the IGZO layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a bottom gate electrode;
a gate insulating layer disposed on the bottom gate electrode;
an active layer disposed on the gate insulating layer, wherein the gate insulating layer is disposed between the bottom gate electrode and the active layer;
a dielectric layer disposed on the active layer;
two interfacial layers formed in first and second portions of the active layer and the first and second portions are separated by the dielectric layer; and
two source/drain electrodes formed on the two interfacial layers respectively, wherein the two source/drain electrodes are electrically connected to the active layer through the interfacial layers respectively and a channel region is form between the two source/drain electrodes.

2. The semiconductor device of claim 1, wherein a material of the gate insulating layer comprises silicon oxide (SiOx), silicon nitride, silicon oxynitride, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium silicate, zirconium aluminate, zirconium oxide, titanium oxide, aluminum oxide (Al₂O₃), a hafnium dioxide-alumina (HfO₂—Al₂O₃) alloy, or a combination thereof.

3. The semiconductor device of claim 1, wherein the active layer comprises at least one of In, Ga, and Zn.

4. The semiconductor device of claim 1, wherein a material of the active layer comprises indium gallium zinc oxide (IGZO), tungsten-doped indium oxide (InWO), indium zinc oxide (InZnO), indium tin oxide (InSnO), Zinc oxide(ZnO), gallium oxide (GaOx), indium oxide (InOx), aluminum zinc oxide (AZO), or a combination thereof.

5. The semiconductor device of claim 1, wherein a material of the bottom gate electrode comprises silver (Ag), aluminum (Al), copper (Cu), tungsten (W), nickel (Ni), titanium (Ti), niobium (Nb), molybdenum (Mo), vanadium (V), cobalt (Co), chromium (Cr) or a combination thereof.

6. The semiconductor device of claim 1, wherein a material of the bottom gate electrode comprises titanium nitride (TiN), tantalum nitride (TaN), tungsten nitride (WN), niobium nitride (NbN), molybdenum nitride (MoN), vanadium nitride (VN), cobalt nitride (CoN), chromium nitride (CrN), nickel nitride (Ni₃N), or a combination thereof.

7. The semiconductor device of claim 1, wherein a material of the source/drain electrodes comprises silver (Ag), aluminum (Al), copper (Cu), tungsten (W), nickel (Ni), titanium (Ti), niobium (Nb), molybdenum (Mo), vanadium (V), cobalt (Co), chromium (Cr) or a combination thereof.

8. The semiconductor device of claim 1, wherein a material of the bottom gate electrode comprises polysilicon or doped silicon.

9. The semiconductor device of claim 1, wherein indium concentration of each of the interfacial layers is higher than indium concentration of the active layer.

10. The semiconductor device of claim 9, wherein the indium concentration of the active layer is in a range between 10¹⁵ and 10¹⁷ atoms/cm³.

11. The semiconductor device of claim 9, wherein the indium concentration of the interfacial layer is in a range between 10¹⁷ and 10¹⁹ atoms/cm³.

12. A method for manufacturing a semiconductor device, comprising:
forming a bottom gate electrode, a gate insulating layer and an active layer in order from bottom to top;
forming a dielectric layer on the active layer;
etching a portion of the dielectric layer to form at least one opening to expose a portion of the active layer;
forming a metal oxide layer on the exposed portion, and an interfacial layer between the active layer and the metal oxide layer being self-formed in the exposed portion;
removing the metal oxide layer to expose the interfacial layer; and
forming a source/drain electrode on the interfacial layer and the source/drain electrode being electrically connected to the active layer through the interfacial layer.

13. The method of claim 12, wherein the bottom gate electrode, the gate insulating layer and the active layer are formed by chemical vapor deposition (CVD), physical vapor deposition (PVD) or atomic layer deposition (ALD).

14. The method of claim 12, wherein the active layer comprises at least one of In, Ga, and Zn, and the metal oxide layer comprises aluminum oxide (AlOx), and the interfacial layer is self-formed by AlOx induced self-intermix methods.

15. The method of claim 14, wherein the interfacial layer comprises indium oxide, wherein indium concentration of the interfacial layer is higher than indium concentration of the active layer.

16. The method of claim 9, wherein the source/drain electrode is form by CVD, PVD or ALD, and excess portions of the source/drain electrode above the dielectric layer is removed by chemical-mechanical polishing.

17. A transistor, comprising:
a bottom gate electrode;
a gate insulating layer disposed on the bottom gate electrode;
an indium gallium zinc oxide (IGZO) layer disposed on the gate insulating layer, wherein the gate insulating layer is disposed between the bottom gate electrode and the IGZO layer;
a first indium oxide layer formed in a first portion of the IGZO layer; and
a first source/drain electrode formed on the first indium oxide layer, wherein the first source/drain electrode is electrically connected to the IGZO layer through the first indium oxide layer, and indium concentration of the first indium oxide layer is higher than indium concentration of the IGZO layer.

18. The transistor of claim 17, wherein the indium concentration of the IGZO layer is in a range between 10¹⁵ and 10¹⁷ atoms/cm³.

19. The transistor of claim 17, wherein the indium concentration of the indium oxide layer is in a range between 10¹⁷ and 10¹⁹ atoms/cm³.

20. The transistor of claim 17, wherein a thickness of the indium oxide layer is lower than a thickness of the IGZO layer.
